(19) United States
(12) Patent Application Publication
(10) Pub. No.: US 2017/0108550 A1
(43) Pub. Date: Apr. 20, 2017

(54) MONITORING DEVICE FOR A SURGE ARRESTER AND MONITORING SYSTEM COMPRISING A MONITORING DEVICE

(71) Applicant: Tridelta Meidensha GMBH, Hermsdorf (DE)

(72) Inventor: Philipp Raschke, Weissenborn (DE)

(21) Appl. No.: 15/295,108

(22) Filed: Oct. 17, 2016

(30) Foreign Application Priority Data
Oct. 16, 2015 (DE) 102015013433.7

(51) Int. Cl. G01R 31/327; G01R 29/08; H02H 9/04; G01R 31/02

(52) U.S. Cl. CPC G01R 31/327; G01R 31/025; G01R 29/08; H02H 9/04

(57) ABSTRACT

The invention relates to a monitoring device for a surge arrester comprising a means 6 for detecting a total leakage current that is flowing between the surge arrester 3 and earth, a field sensor 9 for detecting an electrical field in the vicinity of the surge arrester 3 and a communication unit 13 for the contact less transmission of data to an external device 2, the communication unit 13 being a near-field communication unit for the contact less exchange of data by means of near-field communication (NFC).

The invention relates to a monitoring device for a surge arrester and to a monitoring system comprising such a monitoring device.

In energy networks, surge arresters are usually connected between the current-carrying line and earth. Modern surge arresters comprise so-called varistors, i.e. elements which below a cut-off voltage are very good insulators but, if this cut-off voltage is exceeded, suddenly become very good conductors. The surge arresters serve for protecting other components of the network from overvoltages, such as may be caused for example by lightning strikes or the like. It is usual to leave these surge arresters in the network for a long period of time, i.e. 30 years or more.

Most of the surge arresters that are used today comprise zinc-oxide varistors. These zinc-oxide varistors have the tendency to age over the years, in particular if the surge arrester has repeatedly-responded to an overvoltage, i.e. has repeatedly switched from the insulating state to the conducting state and back. This ageing has the effect that the so-called leakage current, i.e. the current in the insulating state that nevertheless flows through the surge arrester, gradually increases. However, an excessive leakage current is a problem, since it may lead to the surge arresters becoming excessively heated, with a further increase in the leakage current, which in the worst case leads to thermal instability and consequently to the destruction of the surge arrester.

A further problem is possible contamination of the housing of the surge arrester, by which a creepage current along the housing may be made possible.

Since most of the time the surge arresters are incorporated in the network purely in the form of insulators, it is very difficult to check their operational capability.

A monitoring system for a surge arrester is known from EP 1356561 B1. Furthermore “Metalloxid-Ableiter in Hochspannungsnetzen Grundlagen” [principles of metal-oxide arresters in high-voltage networks] Volker Hinrichsen, 3rd edition, copyright © 2012: Siemens AG Energy Sector Freyeslebenstraβe 1 91058 Erlangen, shows a leakage current monitoring device as a device provided outside the surge arrester which measures a leakage current that is flowing at the time through the surge arrester. This involves detecting the peak value of the current. Either the peak value itself is displayed or an apparent root-mean-square value by way of a scaling factor. There is mostly also an integrated surge counter, which counts how often the surge arrester has responded.

Such leakage current monitoring devices are in series with the surge arrester in an earth connection line. More recent developments are based on an evaluation of the 3rd harmonic of the leakage current and use this to evaluate the resistive component. The influence of the 3rd harmonic in the voltage, which can greatly falsify the measurement, is compensated by built-in e-field sensors or field sensors. The measured values can be transmitted by way of a radio interface, so that further evaluation and archiving by means of a computer is possible.

The cited prior art consequently proposes providing a monitoring system chat carries out a recording of the variation over time of the leakage current through the surge arrester, and also of the surge events. By reading out this recording and corresponding evaluation of the results, a forecast of the extent to which the surge arrester still complies with the specifications, or whether an exchange is required, can be given.

According to the cited prior art, the field sensor or e-field sensors is/are connected to earth by way of an earth line, and the current from the field sensor to earth that is caused by the electrical field is measured by a current measuring device.

Provided for supplying the prior-art monitoring system with energy is a circuit which directs the current from the field sensor to earth into an energy store when the monitoring system is not measuring the current.

This has the disadvantage that additional expenditure is required for a switchover, and that also the reliability of the energy supply is only ensured to a restricted extent, in particular whenever the earthing of the field sensor is impaired by environmental influences, corrosion or the like.

It is additionally known to supply the monitoring device with energy by means of a solar cell. This however makes the construction even more expensive and complicated. In addition, solar cells are not capable of reliably supplying the device, for instance at high latitudes (60° and above), during other long periods of darkness or in the case of indoor use.

In connection with a monitoring device which, in the form of a “traffic light”, makes a green, yellow or red light appear but does not otherwise transmit the data to the outside, it is also known to realize the energy supply from the leakage current itself.

The known field sensors are usually arranged in the vicinity of the surge arrester and connected to an earthing line. A current measuring device measures the current between the field sensor and earth continuously or at intervals. The field sensor may be regarded as a voltage source that has a high internal resistance. If it is subjected to the load of a low-impedance circuit, the field sensor voltage breaks down, which may falsify the measured value.

In the prior art, the transmission of the measurement results to the outside took place either by a display device on the monitoring device, that is to say by visual inspection, or by wireless or wired-bound data transmission. Known radio technologies used here are 868 MHz, Zigbee, Wi-Fi, GPRS.

However, with the preferred wireless communication, problems occur if a number of surge arresters with respective monitoring devices are arranged close together, since a unique assignment of the data to the respective surge arresters must be ensured. Furthermore, this type of data transmission requires a considerable amount of energy, and so supplying energy only by means of the leakage current is not sufficient with certainty, for which reason further energy sources, mostly solar cells, have been provided in the prior art.

The object of the invention is therefore to provide an improved monitoring device and an improved monitoring system that do not have these problems.

The object is achieved by a monitoring device according to Claim 1 and by a monitoring system according to Claim 7. The dependent claims relate to further advantageous designs of the invention.

In particular, the invention relates to a monitoring device for a surge arrester comprising a means for detecting a total leakage current that is flowing between the surge arrester and earth, a field sensor for detecting an electrical field in the vicinity of the surge arrester and a communication unit for the contactless transmission of data to an external device. According to the invention, the communication unit is a near-field communication unit for the contactless exchange of data by means of near-field communication (NFC).

Preferably provided is a voltage measuring unit, which detects the voltage at the field sensor.

Also preferably, the invention comprises an energy supply unit, which uses the total leakage current for providing the energy that is supplied to the monitoring device.

In the monitoring device there may also be provided an evaluation logic, which is designed to calculate the amplitude of the second harmonic I₃ᵣ of a resistive component of the leakage current according to the equation:

I₃ᵣ=I₃ₜ−K(I₁ₜ/U₁ₚ)U₃ₚ

where;
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

A data memory serves for storing the amplitude of the 2nd harmonic of the compensated second harmonic of the total leakage current together with a timing mark.

Apart from the amplitude of the second compensated harmonic of the 2nd harmonic of the total leakage current, the invention may also detect a peak value of the total leakage current Iₚₑₐₖ and/or of a power pulse current Iₚᵤₗₛ, the power pulse current Iₚᵤₗₛ being the value of the amplitude of a current pulse when the surge arrester responds. It is similarly possible to provide a surge counter, which counts how often the surge arrester has arrested an overvoltage.

The monitoring system according to the invention for monitoring a surge arrester comprises a monitoring device of the type described above and a receiving unit for wirelessly receiving data from the monitoring device by means of near-field communication.

The invention is described below on the basis of a preferred embodiment and with reference to the figures, in which:

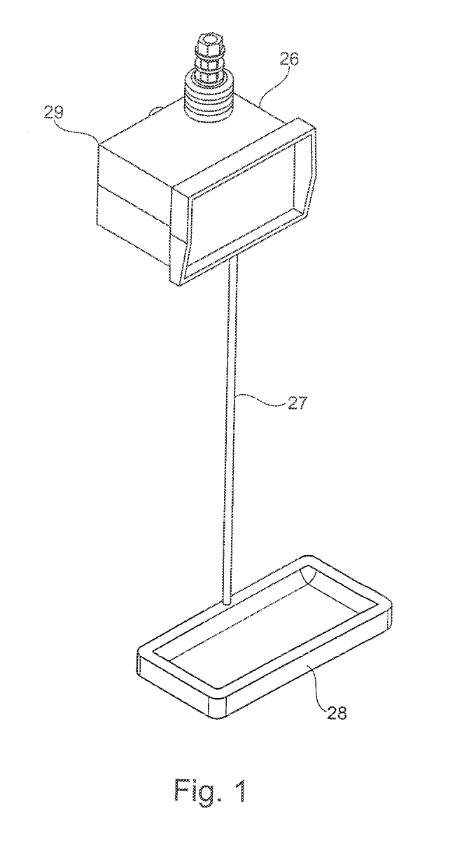

FIG. 1 shows a view of the monitoring device;

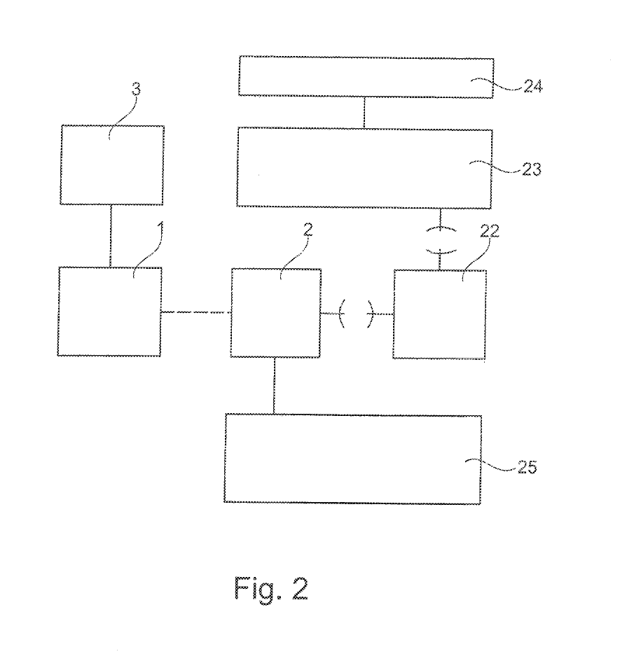

FIG. 2 shows a block diagram of the overall monitoring system;

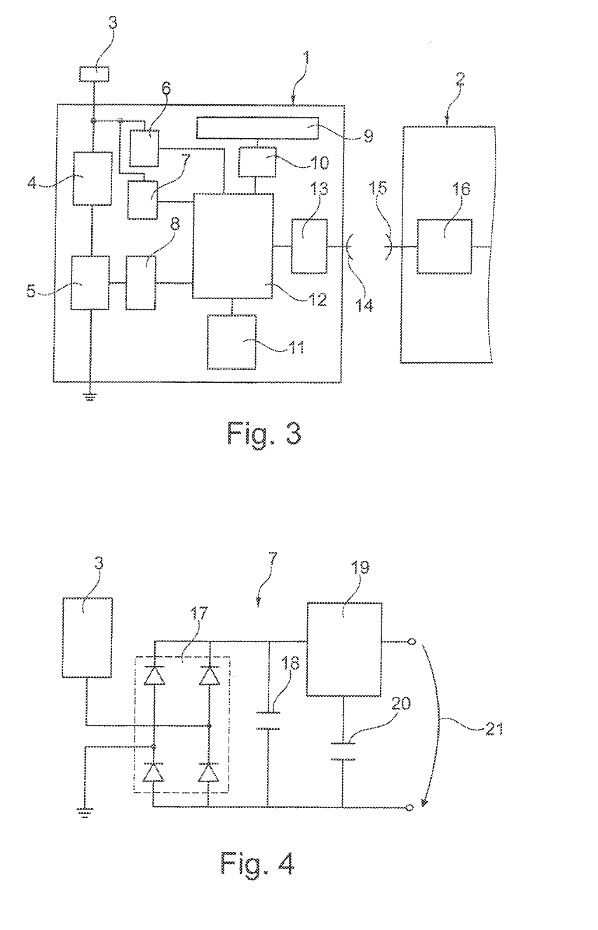

FIG. 3 shows a block diagram of the monitoring device;

FIG. 4 shows a view of a detail in block form of the energy supply; and

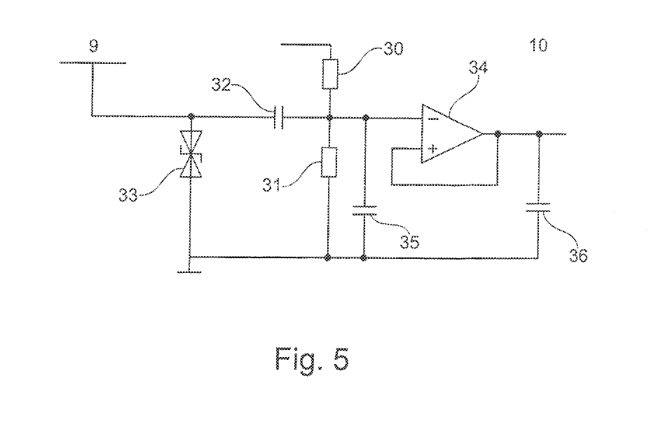

FIG. 5 shows a view of a detail as a circuit diagram of the voltage measurement at the field sensor.

The invention is described below on the basis of a preferred embodiment.

As can be seen in FIG. 1, the monitoring device comprises a monitoring unit 26, which is connected by way of a cable 27 to a transmitting unit 28. The monitoring unit 26 comprises a housing 29, which is to be provided in the direct vicinity of a surge arrester 3 that is not shown.

The housing 29 may comprise a display unit, which visually signals an operating state applicable at the time and/or individual measuring parameters.

The cable 27 extends from the housing 29 of the monitoring unit 26 to the transmitting unit 28. The transmitting unit 28 is usually arranged at some distance from the monitoring unit 26, so that it is accessible for a user without any problem and without any danger.

The transmitting unit 28 is designed in the form that it can serve as a receiving area for a commercially available smartphone 2 with near-field communication means (NFC).

FIG. 2 shows a block diagram of a monitoring system according to the invention.

A surge arrester is schematically indicated by the reference numeral 3. This arrester is connected between the current-carrying line and earth. Connected at the earth-side connection of the surge arrester 3 is the monitoring device 1.

The monitoring device 1 is designed such that it transmits the data to be measured or the processed data contactlessly to a receiving unit 2, for example a smartphone, by way of near-field communication (NFC).

The smartphone 2 may then for its part be connected by way of a cable or other communication means to a commercially available computer 25 or by way of an Internet function to the internet 22 and further by way of suitable websites 23 to a server 24.

In this way it is possible to enter data collected by the smartphone 2 into an overall system conveniently and in a way that is efficient for the operator of the power supply installation, and thus continue so follow the development over time of the performance of the various surge arresters 3 in the network.

FIG. 3 shows in detail a block diagram of the monitoring device 1 from the previous FIG. 2.

As can be seen in FIG. 3, the monitoring device is connected at the earth-side connection of the surge arrester 3.

The reference numeral 4 denotes a gas arrester, which is provided in the monitoring device 1. The function at this gas arrester 4 is described in German Utility Model DE 202015004663.0

Connected in series with this gas arrester 4 is a transformer 5, which generates a voltage pulse when the gas arrester 4 arrests, the voltage pulse being equivalent to the surge current Iₚᵤₗₛₑ through the gas arrester 4. The voltage pulse can then be evaluated by means of a power-pulse-current measuring unit 8. The power-pulse-current measuring unit 8 is for its part connected in turn to a microprocessor 12, which processes the output of the power-pulse-current measuring unit 8. The microprocessor 12 may also be designed as a surge counter and increment a counting value by 1 with every response of the gas arrester 4.

Additionally provided at the high-voltage-side input of the gas arrester 4 is a current measuring unit 6, which is designed for measuring the leakage current through the surge arrester 3 or the creepage current along the surge arrester 3.

The output of the current measuring unit 6 is fed to the microprocessor 12.

The reference numeral 7 denotes an energy supply unit. This is connected in such a way that it receives the leakage current through the surge arrester 3 and converts it into a supply voltage for the microprocessor 12 and the other components of the monitoring device 1. The energy supply unit 7 is described later in still more detail.

The reference numeral 11 denotes a time measuring unit. This is not restricted in any particular way. Any suitable clock may be used here, for example a quartz crystal or the like. It is also possible to derive a measure of time from the network frequency.

The reference numeral 9 denotes a field sensor. This field sensor 9 is designed to detect the electrical field in the vicinity of the surge arrester 3. The output of the field sensor 9 is connected to a voltage measuring unit 10. The voltage measuring unit 10 is explained in more detail later. The output of the voltage measuring unit 10 is fed to the microprocessor 12.

Finally, the reference numeral 13 denotes a communication unit, in particular a near-field communication unit, which allows the measurement data or processed measurement data to be transmitted from the microprocessor 12 to an external device 2, for example a smartphone.

In the case of the preferred embodiment, the microprocessor 12 is programmed in such a way that it calculates the 3rd harmonic I₃ₜ, i.e. the 2nd harmonic of the total leakage current, from the measured value of the current measuring unit 6 by means of Fourier transformation.

In addition, the microprocessor 12 calculates the 3rd harmonic U₃ₚ of the field sensor voltage of the voltage measuring unit 10.

Since the microprocessor 12 also knows from the result of the current measuring unit 6 the amplitude of the total leakage current I₁ₜ and also knows from the result of the voltage measuring unit 10 the amplitude of the total voltage at the field sensor 9, the microprocessor is capable of calculating the so-called compensated 3rd harmonic of the leakage current, i.e. the amplitude of the compensated second harmonic I₃ᵣ of the total leakage current, with the following equation:

I₃ᵣ=I₃ₜ−K(I₁ₜ/U₁ₚ)U₃ₚ

where;
I₃ᵣ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

Constant K is determined empirically, and is typically equal to 0.75.

Experience has shown that the 2nd harmonic thus determined of the resistive leakage current is a good measure for monitoring the ageing process of the surge arrester.

Although it is not shown, there may be further measuring elements in the monitoring device 1, for example a temperature sensor. As an alternative to this, it is also possible to provide a temperature sensor already in the surge arrester 3, and to transmit the measured value of the temperature to the microprocessor 12 of the monitoring device 1 in a suitable way.

The microprocessor 12 is designed to form respective groups of values, which respectively comprise the calculated value of the compensated second harmonic of the total leakage current, a timing mark, a peak value of the leakage current Iₚₑₐₖ and possibly a power-pulse-current peak value Iₚᵤₗₛₑ. The group of values may additionally also comprise a measured temperature value and the value at the time of a surge counter.

During operation, a user entrusted with looking after the surge arrester 3 will places his smartphone 2 onto the transmitting unit 28 in FIG. 1. The transmitting unit 28 and the smartphone 2 will exchange data with one another by way of near-field communication, whereupon the microprocessor 12 is made to transmit the groups of values stored in it to the smartphone 2.

Typically, the identification of the surge arrester is entered into the smartphone once for commissioning. In this case, the smartphone is placed onto the transmitting unit. The monitoring device transmits a unique (permanently burnt-in) ID. The smartphone stores the entered identification and the ID in its memory and transmits it via the Internet into the database.

Alternatively, before placing his smartphone 2 onto the transmitting unit 28, the user may enter the identification of the respective surge arrester 3 by way of the keypad of the smartphone. Since the data transmission takes place by way of near-field communication, the assignment is unique, and there is no risk of data of another surge arrester 3 inadvertently being wrongly assigned.

FIG. 4 snows the energy supply unit 7 of the monitoring device shown in FIG. 3. The energy supply unit 7 comprises a rectifier 17, preferably a bridge rectifier. This bridge rectifier is used to rectify the leakage current of the surge arrester. The leakage current of the surge arrester is in the range of a few milliamperes. Its resistive component is in the μA range.

The energy for operating the monitoring device 1 is preferably obtained from the leakage current by means of an energy collector 19 and also two energy stores, preferably capacitors 18, 20. Since the monitoring device 1 does not monitor the leakage current of the surge arrester 3 continuously, but only at regular intervals, for example once per hour or once per day, the energy from the leakage current is quite sufficient to ensure the operation of the monitoring device 1.

The reading out of the data by way of the near-field communication likewise does not take place continuously, but at regular intervals, for example once a month or once every half year. The energy that can be obtained from the leakage current is also sufficient for this, since the near-field communication manages with a very small amount of energy.

Moreover, energy is even obtained from the NFC transmission. The radio power of the smartphone is converted by way of the NFC receiver into an operating voltage. The transmitting unit consequently supplies itself.

The advantage of this type of construction is that no additional energy source, such as a solar cell or the like, has to be provided.

FIG. 5 finally shows in detail the voltage measuring unit 10. The voltage measuring unit 10 comprises two series-connected resistors 30, 31, which are connected as voltage dividers between the supply voltage and earth.

The output of the field sensor 9 is connected by way of a capacitor 32 to the intermediate point of the voltage divider comprising the resistors 30 and 31. This point is likewise connected to the inverting input of an operational amplifier 34, which is connected as a voltage follower. Two smoothing capacitors 35 and 36 are provided at the input and the output of the operational amplifier 34.

As can be seen in FIG. 5, a TVS diode 33 for voltage protection is connected between the output of the field sensor 9 and earth.

This circuit allows the voltage at the field sensor 9 to be measured without the field sensor itself being directly earthed, apart from by way of the TVS diode 33 serving for voltage protection.

The field sensor 9 is to be regarded as a voltage source that has a high internal resistance. If it is subjected to the load of a low-impedance circuit, the field sensor voltage breaks down. The measuring circuit with a high-impedance voltage-follower circuit does not subject the field sensor to a load and consequently produces unfalsified voltage values.

The capacitor 32, which serves as a decoupling capacitor, blocks DC voltages occurring and consequently avoids errors as a result of an additional voltage offset on the measuring signal.

The monitoring device 1 according to the invention may be retrofitted in the case of all commonly used surge arresters without a spark gap. In this case, an RFID chip or a barcode, which allows a unique identification of the associated surge arrester 3, is provided in the region of the transmitting unit 28. This RFID chip or the barcode is likewise read out by the smartphone 2, in order in this way to ensure a unique assignment of the respective data to a specific surge arrester 3.

It is preferred however for the ID for the unique assignment of the arrester to be permanently stored in a memory of the microprocessor.

Although the invention has been described on the basis of a preferred embodiment, it is not restricted to it. It is clear to a person skilled in the art that various variations and modifications can be performed.

In the case of the preferred embodiment, the conversion of the measured values into the data that are ultimately to be evaluated is carried out in the monitoring device 1. This is not absolutely necessary. It is also possible to store the measured values themselves and then to carry out the conversion in the smartphone 2 after the data transmission.

1. A monitoring device for a surge arrester comprising:
a means (6) for detecting a total leakage current that is flowing between the surge arrester (3) and earth;
a field sensor (9) for detecting an electrical field in the vicinity of the surge arrester (3); and
a communication unit (13) for the contactless transmission of data to an external device (2);
characterized in that
the communication unit (13) is a near-field communication unit for the contactless exchange of data by means of near-field communication (NFC).

2. The monitoring device according to claim 1, characterized by a voltage measuring unit (10), which detects the voltage at the field sensor (9).

3. The monitoring device according to claim 1, characterized by an energy supply unit (5, 7), which uses the total leakage current for providing the energy that supplied to the monitoring device.

4. The monitoring device according to claim 1, characterized by a microprocessor (12), which is designed to calculate the amplitude of the compensated second harmonic of total leakage current I₃ᵣ according to the equation:
I₃ᵣ=I₃ₜ−K(I₁ₜ/U₁ₚ)U₃ₚ
where:
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

5. The monitoring device according to claim 4, characterized by a memory (12) for storing the amplitude of the compensated second harmonic of the total leakage current I₃ᵣ together with a timing mark.

6. The monitoring device according to claim 1, characterized by means (6, 8) for detecting a peak value of the total leakage current Iₚₑₐₖ and/or a power pulse current Iₚᵤₗₛ, the power pulse current Iₚᵤₗₛ being the value of the amplitude of a current pulse when the surge arrester responds.

7. The monitoring device of claim 1 further comprising a monitoring system for monitoring a surge arrester, characterized by a monitoring device further comprising
a receiving unit (2) for wirelessly receiving data from the monitoring device by means of near-field communication.

8. The monitoring device according to claim 2, characterized by an energy supply unit (5, 7), which uses the total leakage current for providing the energy that is supplied to the monitoring device.

9. The monitoring device according to claim 2, characterized by a microprocessor (12), which is designed to calculate the amplitude of the compensated second harmonic of total leakage current I₃ᵣ according to the equation:
I₃ᵣ=I₃ₜ−K(I₁ₜ/U₁ₚ)U₃ₚ
where:
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

10. The monitoring device according to claim 3, characterized by a microprocessor (12), which is designed to calculate the amplitude of the compensated second harmonic of total leakage current I₃ᵣ according to the equation:
I₃ᵣ=I₃ₜ−K(I₁ₜ/U₁ₚ)U₃ₚ
where:
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

11. The monitoring device according to claim 2, characterized by means (6, 8) for detecting a peak value of the total leakage current Iₚₑₐₖ and/or a power pulse current Iₚᵤₗₛ, the power pulse current Iₚᵤₗₛ being the value of the amplitude of a current pulse when the surge arrester responds.

12. The monitoring device according to claim 3, characterized by means (6, 8) for detecting a peak value of the total leakage current Iₚₑₐₖ and/or a power pulse current Iₚᵤₗₛ, the power pulse current Iₚᵤₗₛ being the value of the amplitude of a current pulse when the surge arrester responds.

13. The monitoring device according to claim 4, characterized by means (6, 8) for detecting a peak value of the total leakage current Iₚₑₐₖ and/or a power pulse current Iₚᵤₗₛ, the power pulse current Iₚᵤₗₛ being the value of the amplitude of a current pulse when the surge arrester responds.

14. The monitoring device according to claim 5, characterized by means (6, 8) for detecting a peak value of the total leakage current Iₚₑₐₖ and/or a power pulse current Iₚᵤₗₛ, the power pulse current Iₚᵤₗₛ being the value of the amplitude of a current pulse when the surge arrester responds.

15. A monitoring device for a surge arrester comprising:
a current measuring unit (6) for detecting a total leakage current that is flowing between the surge arrester (3) and earth;
a field sensor (9) for detecting an electrical field in the vicinity of the surge arrester (3); and
a communication unit (13) for the contactless transmission of data to an external device (2); wherein the communication unit (13) is a near-field communication unit for the contactless exchange of data by means of near-field communication (NFC).

16. The monitoring device according to claim 15 further comprising a voltage measuring unit (10), which detects the voltage at the field sensor (9).

17. The monitoring device according to claim 15, further comprising a microprocessor (12), which is designed to calculate the amplitude of the compensated second harmonic of total leakage current I₃ᵣ according to the equation:
I₃ᵣ=I₃ₜ−K(I₁ₜ/U₁ₚ)U₃ₚ
where:
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant.

18. The monitoring device according to claim 15 further comprising an energy supply unit (5, 7), which uses the total leakage current for providing the energy that is supplied to the monitoring device.

19. The monitoring device according to 15 wherein said current measuring unit (6) and a power-pulse-current measuring unit (8) both detect a peak value of the total leakage current Iₚₑₐₖ and/or a power pulse current Iₚᵤₗₛ, the power pulse current Iₚᵤₗₛ being the value of the amplitude of a current pulse when the surge arrester responds.

20. A monitoring device for a surge arrester comprising:
a current measuring unit (6) for detecting a total leakage current that is flowing between the surge arrester (3) and earth;
a field sensor (9) for detecting an electrical field in the vicinity of the surge arrester (3); and
a communication unit (13) for the contactless transmission of data to an external device (2); wherein the communication unit (13) is a near-field communication unit for the contactless exchange of data by means of near-field communication (NFC);
the monitoring device further comprising a microprocessor (12), which is designed to calculate the amplitude of the compensated second harmonic of total leakage current I₃ᵣ according to the equation:
I₃ᵣ=I₃ₜ−K(I₁ₜ/U₁ₚ)U₃ₚ
where:
I₃ₜ is the amplitude of the second harmonic of the total leakage current,
I₁ₜ is the amplitude of the total leakage current;
U₁ₚ is the amplitude of the total voltage at the field sensor;
U₃ₚ is the amplitude of the second harmonic of the voltage at the field sensor; and where
K is a prescribed constant; and
the monitoring device further wherein said current measuring unit (6) and a power-pulse-current measuring unit (8) both detect a peak value of the total leakage current Iₚₑₐₖ and/or a power pulse current Iₚᵤₗₛ, the power pulse current Iₚᵤₗₛ being the value of the amplitude of a current pulse when the surge arrester responds.
